(19) United States
(12) Patent Application Publication
(10) Pub. No.: US 2013/0265032 A1
(43) Pub. Date: Oct. 10, 2013

(54) Monitoring and controlling electrical Instrumentation

(71) Applicant: Frank Joseph PRINEPPI, Freeport (AU)

(72) Inventor: Frank Joseph PRINEPPI, Freeport (AU)

(21) Appl. No.: 13/798,979

(22) Filed: Mar. 13, 2013

(30) Foreign Application Priority Data
Mar. 29, 2012 (GB) GB 1205583.6

(51) Int. Cl. G01R 19/00

(52) U.S. Cl. CPC G01R 19/00
USPC 324/72

(57) ABSTRACT

External monitoring and control apparatus and associated method comprising means to continuously provide a precision reference voltage to an internal monitoring instrument such as a cathodic monitoring instrument operable, in use, to monitor externally produced voltage and/or current signals indicative of rectifier current, rectifier voltage and soil potential in the system being monitored, wherein the normally continuous supply of precision reference voltage is interruptable by a Reed relay connectable in its open position to a source of incoming measurement signals indicative of current and/or voltage parameters relating to the system being monitored by the internal monitoring instrument, the arrangement being such that the internal monitoring instrument is only briefly in direct electrical contact with the system being monitored when external monitoring occurs via the external monitoring and control apparatus.

This invention relates to electrical monitoring and control instrumentation, such as those typically used to regularly monitor the performance of cathodic protection monitoring devices used in conjunction with rectifiers providing dc Impressed Current Cathodic Protection (ICCP) for gas pipelines in order to prevent or inhibit cathodic corrosion.

### BACKGROUND TO THE INVENTION

It is well known that ICCP rectifiers protecting corrosion in, e.g. pipelines are particularly vulnerable to transient high voltages from lightening strikes arising in the power lines delivering power to the ICCP rectifier units. These transients can be from lightning strikes near the power lines, tens of miles away and can carry very destructive energy levels. Delicate instrumentation used to monitor the rectifier voltages and currents are vulnerable to such transients. These instruments typically measure and monitor signal levels in the micro-volt range. Devices such as gas discharge tubes and voltage suppressing semiconductor devices are used to help mitigate the effect of such destructive voltages on the instruments. However, in practice it is found that transient voltages can still get through these transient suppression devices at such levels as to cause damage and destruction to the delicate components.

A further requirement of the instruments utilised to collect the data is accuracy and stability of the measurements with component aging and operation over very wide temperature ranges found in the field which can be sub-zero temperatures in winter to desert-heat in the summer. Voltage measurements required in the instruments generally place high demands on the amplifier designs that are difficult to maintain over time and in diverse ambient conditions.

The performance of the electronic components will generally drift beyond accepted limits unless complex temperature compensation devices are utilized. Such long-term drift inevitably causes the component stability to deteriorate, placing the accuracy of the instrument into question. This can lead to additional man-hours being required in routine field calibration, negating the main purpose of using remote monitoring devices in the first place.

The present invention serves to provide a solution to both the lightning-induced transient voltage issues as well as maintaining long-term instrument accuracy under extreme temperature conditions, and deterioration with age, of the instrumentation electronics.

### SUMMARY OF THE INVENTION

According to a first aspect of the invention there is provided external monitoring and control apparatus and associated method comprising means to continuously provide a precision reference voltage to an internal monitoring instrument such as a cathodic monitoring instrument operable, in use, to monitor externally produced voltage and/or current signals indicative of rectifier current, rectifier voltage and soil potential in the system being monitored, wherein the normally continuous supply of precision reference voltage is interruptable by a Reed relay connectable in its open position to a source of incoming measurement signals indicative of current and/or voltage parameters relating to the system being monitored by the internal monitoring instrument, the arrangement being such that the internal monitoring instrument is only briefly in direct electrical contact with the system being monitored when external monitoring occurs via the external monitoring and control apparatus.

With this arrangement it will be apparent that the risk of damage to the monitoring instrument due to unwanted transient voltages, such as from lightening strikes, only occurs at the time when external monitoring and control of the internal monitoring instrument occurs, which may typically take only several seconds, whereafter the internal monitoring instrument is essentially separated from the system being monitored by a contact-set air gap provided by a reed or mechanical relay, with the internal monitoring instrument itself being continuously supplied with a reference voltage generated by a high-precision, temperature stabilised, active voltage reference source. The reference source being highly stabilized using electronic temperature compensation, thereby reducing the precision criteria applicable to all signal measurements to that of a single stabilized voltage reference element.

Preferably, the external monitoring and control apparatus is configured to calibrate the reference signal immediately before the Reed relay is switched to monitor incoming electrical signals from the system being monitored by the internal monitoring instrument(s), such that any “drift” or changes in the transfer function of the instrumentation amplifiers, caused through temperature variations or equipment age, is accounted for and corrected each time a measurement is made, and immediately prior to connecting the system being monitored to the monitoring instruments via the Reed relay.

According to a second aspect of the invention there is provided a method of externally monitoring and controlling internal monitoring instruments such as cathodic protection monitoring instruments operable, in use, to monitor externally produced voltage and/or current signals indicative of rectifier current, rectifier voltage and soil potential in the system being monitored, wherein the method includes using a Reed relay to provide a normally continuous precision reference voltage when the Reed relay is in its closed condition and, prior to opening the Reed relay for subsequent direct monitoring of the electrical system, calibrating the internal reference signal to compensate for any changes from previously obtained measurement signals caused by e.g. temperature variations and/or equipment age.

### BRIEF DESCRIPTION OF THE DRAWINGS

The invention will now be described, by way of example only, with reference to the accompanying drawings in which:

FIG. 1 is a schematic view of apparatus according to the first embodiment of the invention installed above ground, and FIG. 2 is a simplified circuit diagram for part of the apparatus in FIG. 1.

### DETAILED DESCRIPTION OF THE DRAWINGS

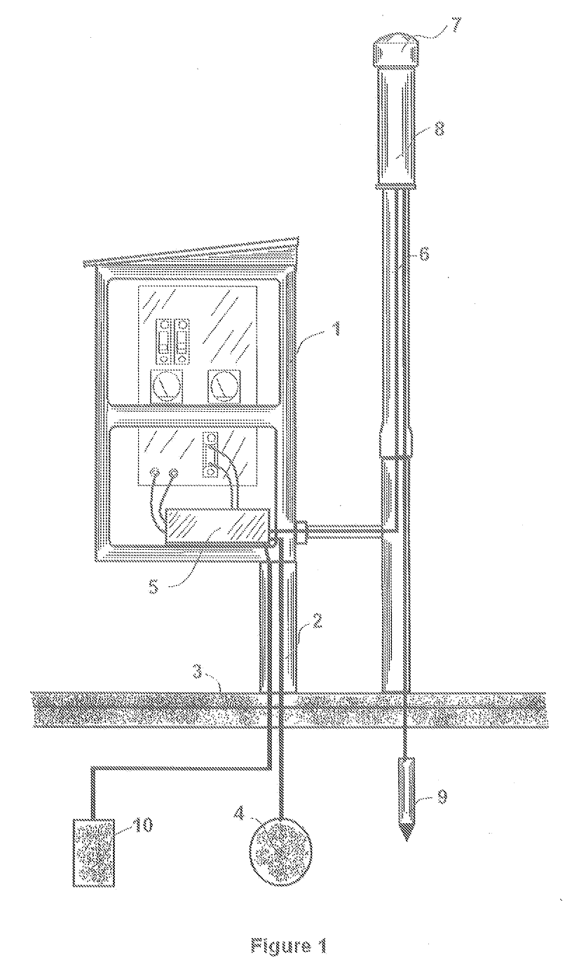

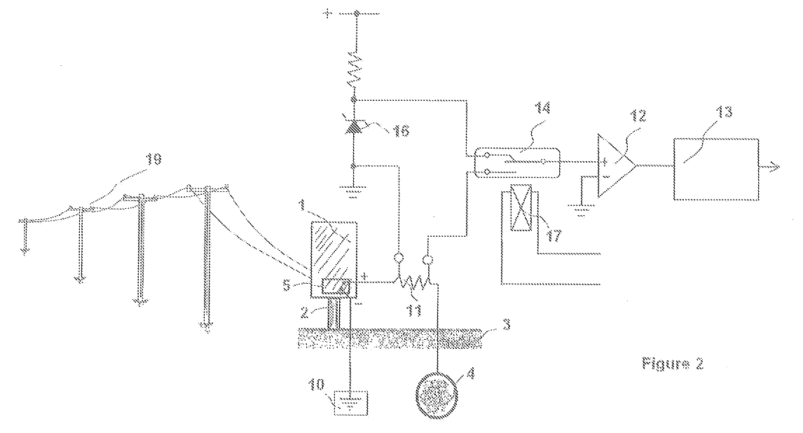

In FIG. 1 there is shown a side view of a rectifier housing 1 mounted on a support post 2 above ground 3, below which is a pipeline 4 electrically connected to a relay box 5 within the housing 1. Behind the housing 1 is a tubular support post 6 having a closed end cap 7 below which is a communications housing 8 containing a GSM cellular transmitter/receiver/antennas with application specific interface hardware providing communication. The Communications housing 8 also includes an instrumentation package in the form of a control PCB electrically connected to several signal sources inside the Rectifier housing, being measured or monitored, including a buried silver-silver chloride reference cell 9, an electrically bonded ground bed 10, a pipeline structure 4 being protected and to the relay box 5, that is used to control the rectifier system With this general arrangement remote SMS monitoring and control of the functioning of a rectifier (not shown) within the housing 1 is made possible, the rectifier itself providing Impressed Current Cathodic Protection for the pipeline 4. Ordinarily, internal instrumentation is provided to monitor the performance of the rectifier primary parameters such as silver-silver chloride Soil potential, Rectifier impressed Voltage, Impressed current as well as local environment parameters such as temperature, line power loss, back up battery level and intrusion security signals. As will be appreciated, this general arrangement is susceptible to high voltage transients due to e.g. lightening strikes and hence an aspect of the present invention is the realisation that it is unnecessary to permanently electrically connect such delicate monitoring and control instrumentation to the internal system being monitored, such as cathodic protection monitoring and a solution to this problem is shown with reference to FIG. 2.

In FIG. 2 there is shown part of a simplified circuit diagram for use with the apparatus of FIG. 1 and in accordance with the method of the second embodiment of the invention, in which it will be seen that an incoming measurement signals is shown by example, as the Rectifier current through metering shunt 11, are physically separated from an instrumentation amplifier 12 and analogue to digital converter 13 by an air gap provided by a normally closed Reed relay 14 openable by a coil 17. In the closed condition shown the Reed relay 14 provides the instrumentation amplifier 12 with a precision reference voltage from the Precision Zener or other thermally stabilized reference source 16. As such, the instrumentation amplifier 12 and analogue to digital converter 13 are not electrically connected to the incoming measurement signals 11 and any potentially damaging transient voltages arriving via power lines 19 through the rectifier 1 and adjoining circuitry 5, until a measurement is to be taken where, in accordance with an aspect of the invention, a calibration reading of the Reference Voltage source 15, is taken immediately before the Reed relay 14 is activated by the coil 17 whereupon the milli-volt current shunt measurement signal 11, is then electrically connected to the instrumentation amplifier 12 and analogue to digital converter 13. Since such measurement and recording steps typically only take several seconds it will be apparent that the invention provides an apparatus and a method by which internal monitoring equipment of this nature is insulated from transient voltages and is therefore only exposed to them for very short periods when readings are being taken.

What I claim is:

1. External monitoring and control apparatus and associated method comprising means to continuously provide a precision reference voltage to an internal monitoring instrument such as a cathodic monitoring instrument operable, in use, to monitor externally produced voltage and/or current signals indicative of rectifier current, rectifier voltage and soil potential in the system being monitored, wherein the normally continuous supply of precision reference voltage is interruptable by a Reed relay connectable in its open position to a source of incoming measurement signals indicative of current and/or voltage parameters relating to the system being monitored by the internal monitoring instrument, the arrangement being such that the internal monitoring instrument is only briefly in direct electrical contact with the system being monitored when external monitoring occurs via the external monitoring and control apparatus.

2. External monitoring and control apparatus according to claim 1 wherein it is configured to calibrate the reference signal immediately before the Reed relay is switched to monitor incoming electrical signals from the system being monitored by the internal monitoring instrument(s).

3. A method of externally monitoring and controlling internal monitoring instruments such as cathodic protection monitoring instruments operable, in use, to monitor externally produced voltage and/or current signals indicative of rectifier current, rectifier voltage and soil potential in the system being monitored, wherein the method includes using a Reed relay to provide a normally continuous precision reference voltage when the Reed relay is in its closed condition and, prior to opening the Reed relay for subsequent direct monitoring of the electrical system, calibrating the internal reference signal to compensate for any changes from previously obtained measurement signals caused by e.g. temperature variations and/or equipment age.
